(19) United States
(12) Patent Application Publication
(10) Pub. No.: US 2026/0239573 A1
(43) Pub. Date: Aug. 13, 2026

(54) HEAT DISSIPATION DEVICE AND ELECTRONIC EQUIPMENT HAVING THE SAME

(71) Applicants: CHAMP TECH OPTICAL (FOSHAN) CORPORATION, Foshan (CN); HON HAI PRECISION INDUSTRY CO., LTD., New Taipei (TW)

(72) Inventors: WEN-HSIEN LIN, New Taipei (TW); Chun-An Chen, New Taipei (TW)

(21) Appl. No.: 19/188,764

(22) Filed: Apr. 24, 2025

(30) Foreign Application Priority Data
Feb. 8, 2025 (CN) 202510139221.5

(51) Int. Cl. H05K 7/20

(52) U.S. Cl. CPC H05K 7/2049; H05K 7/20272

(57) ABSTRACT

A heat dissipation device includes a heat-conducting mounting assembly and a heat dissipation mechanism including a first heat dissipation assembly and a second heat dissipation assembly, each of the first and second heat dissipation assemblies is detachably connected and inserted in the heat-conducting mounting assembly, and comprises a bearing member, a heat dissipation member, a magnetic member, and a magnetic pressing member. The bearing member is arranged on a side of the heat-conducting mounting assembly and a receiving groove penetrates the bearing member, the heat dissipation member is arranged in the receiving groove, a part of the heat dissipation member protrudes out of the receiving groove and extends into the heat-conducting mounting assembly, the magnetic member is arranged in the heat dissipation member, the magnetic pressing member covers the receiving groove, the magnetic pressing member is used to act on the magnetic member through a magnetic force.

### FIELD

The subject matter herein relates to a field of heat dissipation technology, and specifically to a heat dissipation device and an electronic equipment having the heat dissipation device.

### BACKGROUND

At present, a traditional air-cooling heat dissipation method is increasingly difficult to meet the heat dissipation requirements of high-power communication equipment, so liquid cooling has become an important application direction in the field of heat dissipation of communication equipment. The current liquid cooling heat dissipation assembly is usually installed on a side of the communication equipment. Since a gap is easily formed between the liquid cooling heat dissipation assembly and the optical module during use, the heat dissipation effect of the liquid cooling heat dissipation assembly is poor.

Therefore, there is room for improvement within the art.

### BRIEF DESCRIPTION OF THE DRAWINGS

Implementations of the present technology will now be described, by way of example only, with reference to the attached figures.

FIG. 1 is a structural schematic view of an electronic equipment according to an embodiment of the present disclosure.

FIG. 2 is a structural schematic view of a heat dissipation device according to an embodiment of the present disclosure.

FIG. 3 is an exploded view illustrating a heat dissipation device according to an embodiment of the present disclosure.

FIG. 4 is another exploded view illustrating a heat dissipation device according to an embodiment of the present disclosure.

FIG. 5 is an exploded view illustrating a heat dissipation mechanism according to an embodiment of the present disclosure.

FIG. 6 is a cross-sectional view illustrating the heat dissipation device taken along A-A line in FIG. 2.

FIG. 7 is an enlarger schematic diagram illustrating a partial area B of the heat dissipation device in FIG. 6.

FIG. 8 is a structural schematic view of a sealing member according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

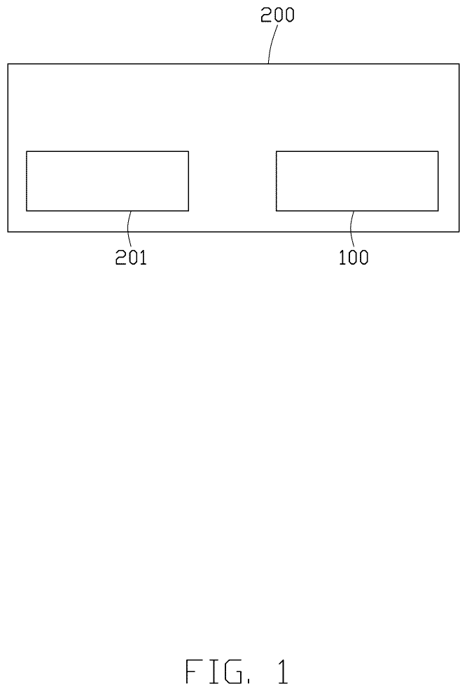

FIG. 1 illustrates an embodiment of an electronic equipment 200. The electronic equipment 200 includes a heat dissipation device 100 and a component 201 to be cooled.

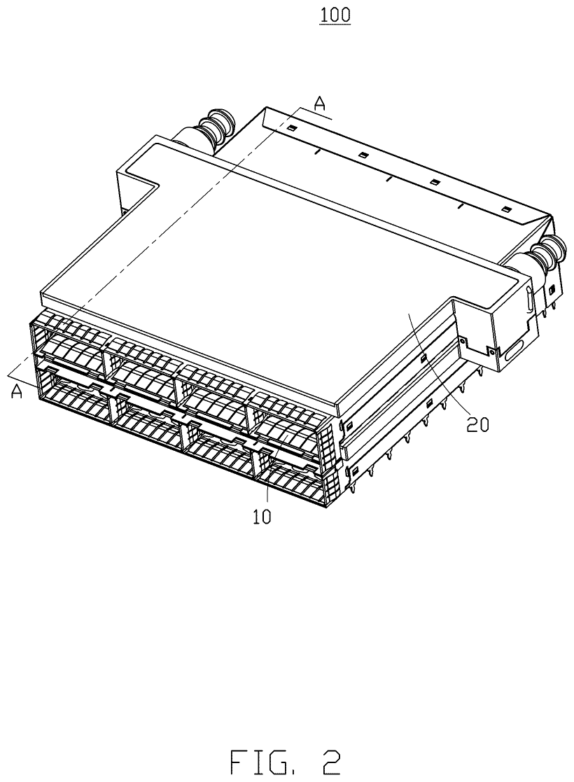

FIG. 2 illustrates an embodiment of a heat dissipation device 100. The heat dissipation device 100 is used to dissipate heat from the component to be cooled to reduce the temperature of the component to be cooled. The heat dissipation device 100 includes a heat-conducting mounting assembly 10 and a heat dissipation mechanism 20.

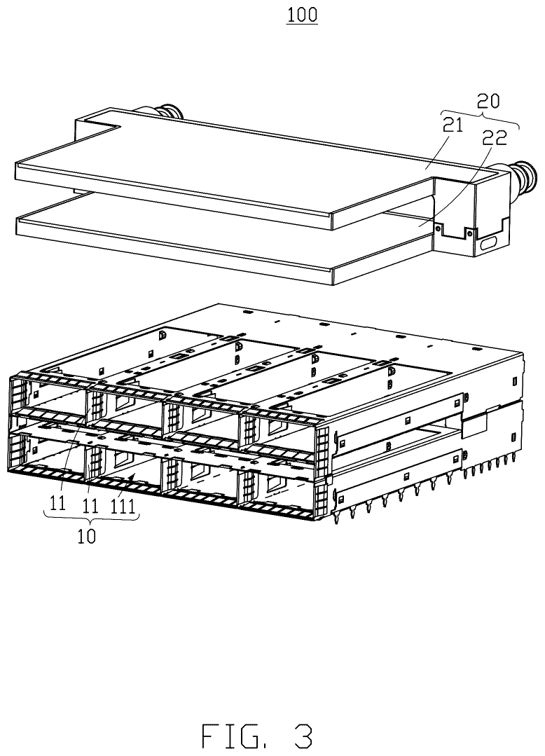

Referring to FIG. 3, the heat-conducting mounting assembly 10 is used to install the component to be cooled and cooperate with the component to be cooled in a heat-conducting manner. The heat-conducting mounting assembly 10 may include two stacked heat-conducting mounting members 11. Each of the heat-conducting mounting members 11 may include four insertion holes 111 arranged side by side. Each insertion hole 111 is used to install a component to be cooled. In the illustrated embodiment, the component to be cooled may be an optical module, but it is not limited thereto. It can be understood that optical modules are widely used in cloud computing, artificial intelligence, big data and other scenarios, and support high-speed data transmission. The optical module is a core component in the optical fiber communication system, which is composed of optoelectronic devices, functional circuits and optical interfaces, etc., and is mainly used to realize the conversion of electrical-optical and optical-electrical signals. The transmitting end of the optical module converts an electrical signal into an optical signal, and after transmission through the optical fiber, the receiving end converts the optical signal into an electrical signal.

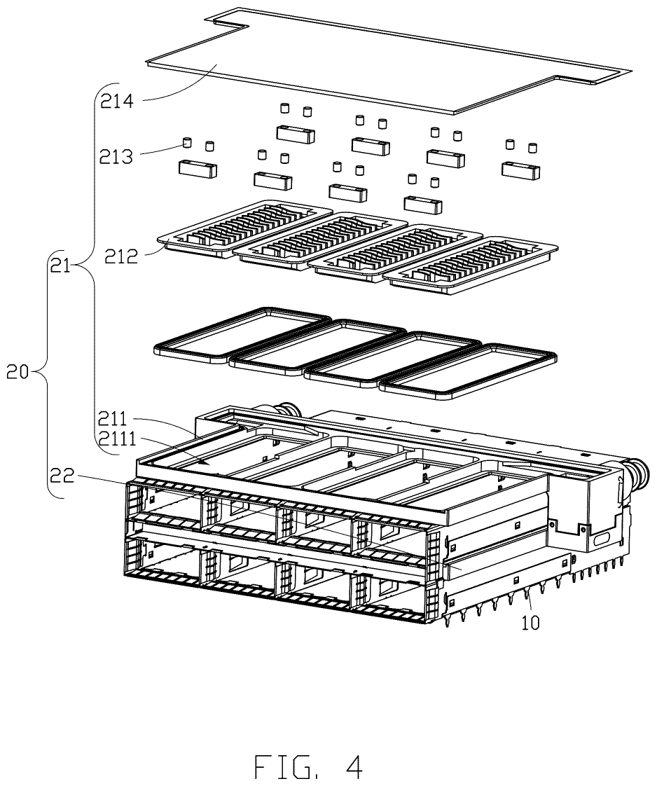

Referring to FIG. 4, the heat dissipation mechanism 20 includes a first heat dissipation assembly 21 and a second heat dissipation assembly 22. The first heat dissipation assembly 21 and the second heat dissipation assembly 22 are detachably connected and inserted in the heat-conducting mounting assembly 10. Each of the first heat dissipation component 21 and the second heat dissipation component 22 includes a bearing member 211, a heat dissipation member 212, a magnetic member 213 and a magnetic pressing member 214. The bearing member 211 is arranged on a side of the heat-conducting mounting assembly 10 and a receiving groove 2111 penetrates the bearing member 211. The heat dissipation member 212 is arranged in the receiving groove 2111, and a part of the heat dissipation member 212 protrudes out of the receiving groove 2111 and extends into the heat-conducting mounting assembly 10 for abutting against the component to be cooled in the heat-conducting mounting assembly 10. The magnetic member 213 is arranged in the heat dissipation member 212. The magnetic pressing member 214 is arranged in a notch of the receiving groove 2111 of the bearing member 211 and is located on a side of the heat dissipation member 212 facing away from the heat-conducting mounting assembly 10. The magnetic pressing member 214 acts on the magnetic member 213 through magnetic force, so that the magnetic member 213 abuts against the heat dissipation member 212, and the heat dissipation member 212 presses against the component to be cooled in the heat-conducting mounting assembly 10. That is, the magnetic pressing member 214 is used to allow the magnetic member 213 to abut against the heat dissipation member 212 and allow the heat dissipation member 212 to press against the component to be cooled in the heat-conducting mounting assembly 10.

In the above heat dissipation device 100, the component to be cooled is installed on the heat-conducting mounting assembly 10 and the heat of the component to be cooled can be transferred to the heat-conducting mounting assembly 10, the first heat dissipation assembly 21 and the second heat dissipation assembly 22 are detachably connected and inserted in the heat-conducting mounting assembly 10, the magnetic pressing member 214 is used to allow the magnetic member 213 to abut against the heat dissipation member 212 and allow the heat dissipation member 212 to press against the component to be cooled in the heat-conducting mounting assembly 10. In this way, the heat of the component to be cooled can be transferred to the heat dissipation member 212 for heat dissipation. Since the heat dissipation member 212 presses against the component to be cooled in the heat-conducting mounting assembly 10 during the whole process, the heat dissipation member 212 and the component to be cooled can be stably fitted together without any gap. The heat dissipation member 212 can continuously dissipate the heat transferred from the component to be cooled, and the heat dissipation effect is better.

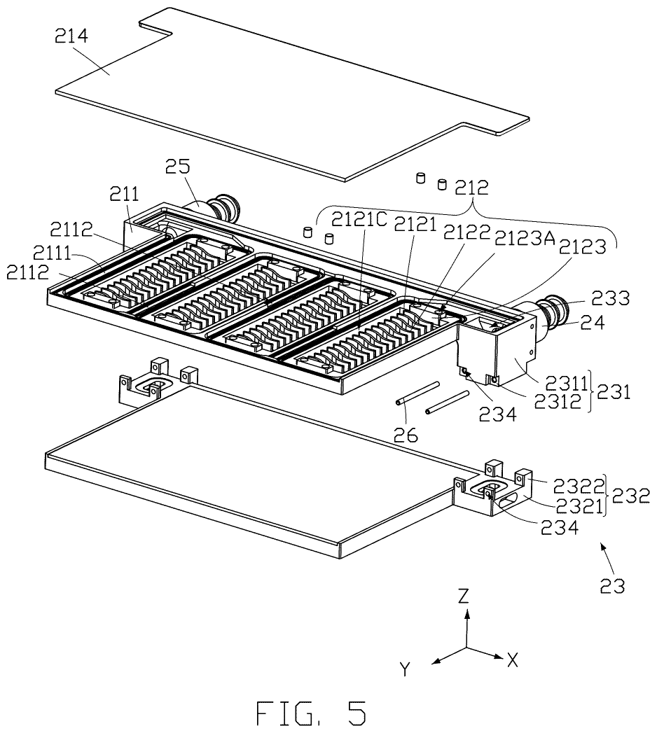

Referring to FIG. 5, in at least one embodiment, the heat dissipation mechanism 20 may further include two connecting assemblies 23, a liquid inlet member 24 and a liquid outlet member 25. The two connecting assemblies 23 are respectively arranged on opposite sides of the bearing members 211 and communicate with the receiving groove 2111 of each of the bearing members 211. The liquid inlet member 24 communicates with one of the two connecting assemblies 23, and the liquid outlet member 25 communicates with the other of the two connecting assemblies 23. The liquid introduced from the liquid inlet member 24 enters the receiving grooves 2111 of the bearing members 211 through the connecting assembly 23 connected to the liquid inlet member 24, flows into the connecting assembly 23 connected to the liquid outlet member 25 after passing through the heat dissipation member 212, and flows out from the liquid outlet member 25. In the illustrated embodiment, the liquid inlet member 24 and the liquid outlet member 25 may be both tubular structures, the liquid introduced into the liquid inlet member 24 may be water, but is not limited thereto, as long as it is a liquid that can cool down the component to be cooled. In this way, by introducing the liquid into the liquid inlet member 24, the liquid first flows into the receiving grooves 2111 of the bearing members 211 from the connecting assembly 23 connected to the liquid inlet member 24, then the liquid flows into the heat dissipation member 212, then the liquid flows through the heat dissipation member 212 and flows into the liquid outlet member 25 from the connecting assembly 23 connected to the liquid outlet member 25, and finally the liquid flows out from the liquid outlet member 25. During the liquid flow process, the heat transferred by the component to be cooled can be taken away, and the component to be cooled can be cooled.

In at least one embodiment, each of the two connecting assemblies 23 includes a first connection member 231 and a second connection member 232. The first connection member 231 is connected to the bearing member 211 of the first heat dissipation assembly 21, the second connection member 232 is connected to the bearing member 211 of the second heat dissipation assembly 22. A receiving chamber 233 communicating with the receiving groove 2111 of each of the bearing members 211 is formed between the first connection member 231 and the second connection member 232, and the liquid inlet member 24 and the liquid outlet member 25 are both connected to the first connection member 231 and are both in communication with the receiving chamber 233. In this way, by forming the receiving chamber 233 connected to the receiving groove 2111 of each of the bearing members 211 between the first connection member 231 and the second connection member 232, the liquid introduced by the liquid inlet member 24 can flow into the bearing member 211 of the first heat dissipation assembly 21 and the bearing member 211 of the second heat dissipation assembly 22 through the receiving chamber 233, thereby dissipating the heat of the components to be cooled. In some embodiments, the first connection member 231 and the corresponding bearing member 211 may be integrally formed, and the second connection member 232 and the corresponding bearing member 211 may be integrally formed. In some embodiments, the first connection member 231 and the corresponding bearing member 211 may be separatable structures, and the second connection member 232 and the corresponding bearing member 211 may be separatable structures.

In at least one embodiment, the first connection member 231 may include a first connecting body 2311 and a recessed portion 2312. The first connecting body 2311 may be a block structure. The first connecting body 2311 is arranged on a side of the corresponding bearing member 211, and an end of the first connecting body 2311 is connected to the corresponding bearing member 211. The recessed portion 2312 is recessed from another end of the first connecting body 2311. The second connection member 232 may include a second connecting body 2321 and a protruding portion 2322. The second connecting body 2321 may be a block structure. The second connecting body 2321 is arranged on a side of the corresponding bearing member 211 and the second connecting body 2321 corresponds to the first connecting body 2311. An end of the second connecting body 2321 is connected to the corresponding bearing member 211, and the protruding portion 2322 is protruding from another end of the second connecting body 2321 and inserted into the recessed portion 2312. The receiving chamber 233 is formed between the first connecting body 2311 and the second connecting body 2321. In the illustrated embodiment, there are four recessed portions 2312 located at the four corners of the first connecting body 2311, and there are four protruding portions 2322 located at the four corners of the second connecting body 2321. The protruding portions 2322 are block-shaped and match the shape of the recessed portions 2312. By providing the protruding portions 2322 and the recessed portions 2312, the first connecting body 2311 and the second connecting body 2321 can be clamped together, and a connection between the first connecting body 2311 and the second connecting body 2321 is more stable.

In at least one embodiment, connecting holes 234 may be provided at corresponding positions of the protruding portion 2322 and the recessed portion 2312, and the heat dissipation mechanism 20 may further include a connecting pin 26, which is inserted into the connecting holes 234. In the illustrated embodiment, a connecting hole 234 is provided on each of the protruding portions 2322 and the recessed portions 2312; there are two connecting pins 26, and each of the two connecting pins 26 is inserted into two protruding portions 2322 and two recessed portions 2312. By providing the connecting holes 234 and the connecting pins 26 and inserting the connecting pins 26 into the connecting holes 234, a fixed connection between the first connecting body 2311 and the second connecting body 2321 can be achieved, and the installation and removal of the connecting pins 26 are relatively convenient.

In at least one embodiment, the bearing member 211 may include a plurality of receiving grooves 2111 arranged side by side along a first direction, and a connecting notch 2112 is provided on a groove wall extending along a second direction perpendicular to the first direction between any two adjacent receiving grooves 2111 of the plurality of receiving grooves 2111, and the connecting notch 2112 communicates with the two adjacent receiving grooves 2111. Any two adjacent connecting notches 2112 are arranged in a staggered manner. In the illustrated embodiment, the first direction is the X-axis direction, the second direction is the Y-axis direction, there are four receiving grooves 2111, and the groove walls of the four receiving grooves 2111 have a total of three connecting notches 2112, and the three connecting notches 2112 may be distributed in an S shape. In this way, the liquid introduced by the liquid inlet member 24 can flow into the plurality of receiving grooves 2111 in sequence through the receiving chamber 233, and the flow path is the longest, which can take away more heat transferred by the component to be cooled, and the heat dissipation effect is better.

In at least one embodiment, the heat dissipation member 212 may include a heat dissipation body 2121 and a plurality of fins 2122 connected to the heat dissipation body 2121. The heat dissipation body 2121 is arranged in the receiving groove 2111, and a portion of the heat dissipation body 2121 protrudes from the receiving groove 2111 into the heat-conducting mounting assembly 10 and is used to abut against the component to be cooled in the heat-conducting mounting assembly 10. The heat dissipation body 2121 may further include a mounting groove 2121C, and the plurality of fins 2122 are arranged at intervals along the second direction in the mounting groove 2121C. By arranging the plurality of fins 2122 at intervals in the mounting groove 2121C of the heat dissipation body 2121, the liquid flowing into the mounting groove 2121C can flow through the plurality of fins 2122 in sequence, thereby taking away the heat transferred by the component to be cooled.

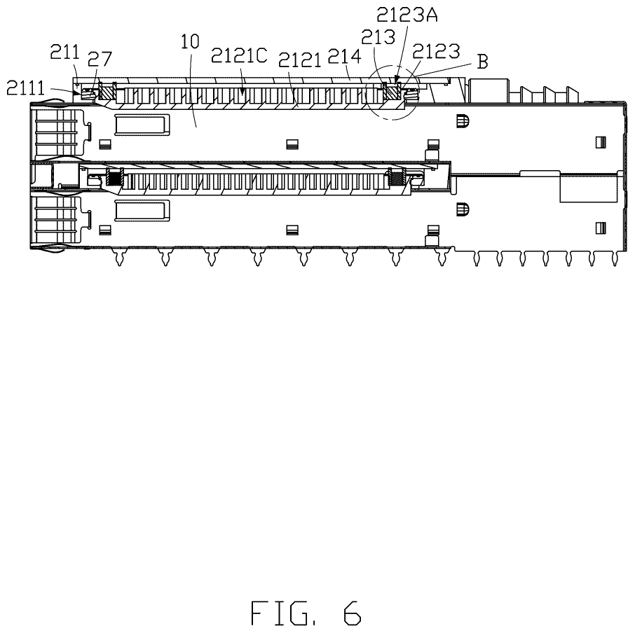

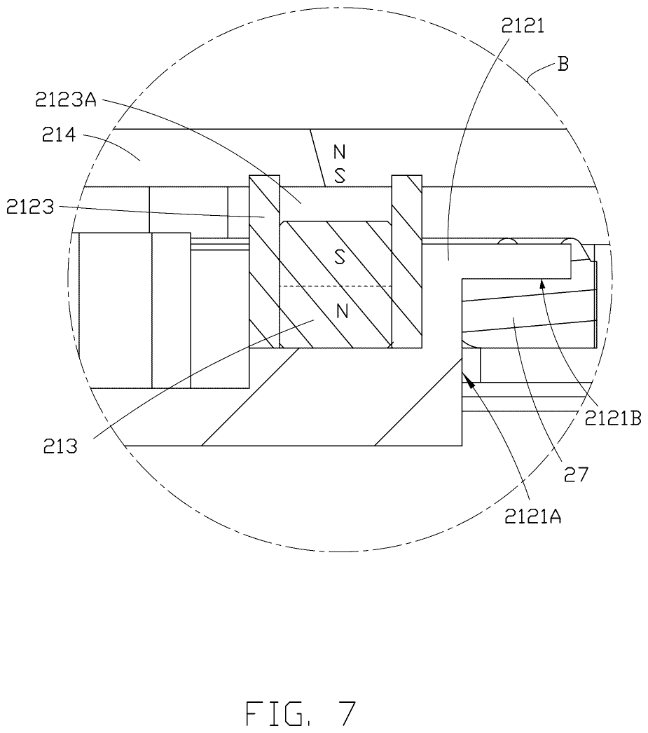

Referring to FIGS. 6 and 7, in at least one embodiment, the heat dissipation member 212 may further include a mounting body 2123. The mounting body 2123 may be connected to a side of the heat dissipation body 2121. The mounting body 2123 may include a slot 2123A, and the magnetic member 213 is arranged in the slot 2123A. The magnetic pressing member 214 is used to act on the magnetic member 213 through a repulsive magnetic force, so that the magnetic member 213 abuts against the heat dissipation member 212. In the illustrated embodiment, the mounting body 2123 may be plate-shaped, and there are two mounting bodies 2123 arranged on opposite sides of the heat dissipation body 2121. Two cylindrical slots 2123A are provided on each of the two mounting bodies 2123. The magnetic member 213 is a magnet and the number is equal to the slots 2123A. An upper portion of the magnetic member 213 installed in the slot 2123A is an S pole, and a lower portion of the magnetic member 213 installed in the slot 2123A is an N pole. A lower part of the magnetic pressing member 214 covering the bearing member 211 is an S pole, and an upper part of the magnetic pressing member 214 covering the bearing member 211 is an N pole. In this way, the magnetic pressing member 214 can act on the magnetic member 213 through the repulsive magnetic force, so that the magnetic member 213 can abut against the heat dissipation member 212. In addition, by setting the mounting body 2123, the installation and disassembly of the magnetic member 213 becomes more convenient.

In at least one embodiment, the heat dissipation mechanism 20 may further include a sealing member 27, and the sealing member 27 is arranged in the receiving groove 2111 and between the bearing member 211 and the heat dissipation body 2121. The sealing member 27 is used to seal a gap between the bearing member 211 and the heat dissipation body 2121. In the illustrated embodiment, the sealing member 27 may be annular and made of silicone. In this way, the sealing member 27 can seal the gap between the bearing member 211 and the heat dissipation body 2121, thereby preventing liquid from flowing from the heat dissipation body 2121 into the heat-conducting mounting assembly 10.

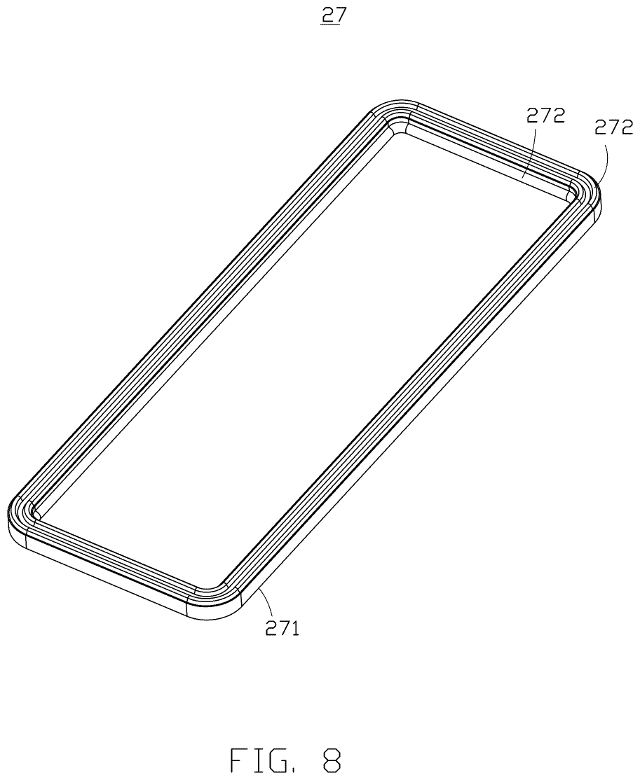

Referring to FIG. 8, in at least one embodiment, the sealing member 27 may include a sealing body 271 and sealing protrusions 272. The sealing body 271 is arranged between the receiving groove 2111 and the heat dissipation body 2121. The heat dissipation body 2121 includes two adjacent surfaces corresponding to the sealing body 271. Each of the sealing protrusions 272 protrudes from a surface of the sealing body 271 facing the heat dissipation body 2121. In at least one embodiment, the heat dissipation body 2121 may be a T-shaped structure. The two adjacent surfaces of the heat dissipation body 2121 corresponding to the sealing body 271 are a first abutting surface 2121A and a second abutting surface 2121B. The first abutting surface 2121A and the second abutting surface 2121B are vertically connected. One of the sealing protrusions 272 is disposed on a side of the sealing body 271 facing the first abutting surface 2121A. Two of the sealing protrusions 272 are arranged at intervals on a side of the sealing body 271 facing the second abutting surface 2121B. Each of the sealing protrusions 272 is an annular structure. By providing the sealing protrusions 272 on the surfaces of the sealing body 271 corresponding to the heat dissipation body 2121, the sealing protrusion 272 abuts against the heat dissipation body 2121, so that the sealing between the receiving groove 2111 and the heat dissipation body 2121 is better, and the gap between the receiving groove 2111 and the heat dissipation body 2121 can be more effectively blocked, thereby preventing liquid from flowing from the heat dissipation body 2121 into the heat-conducting mounting assembly 10. In some embodiments, the sealing body 271 and the sealing protrusions 272 are an integral structure. In some embodiments, the sealing body 271 and the sealing protrusions 272 are separatable structures.

A use process of the heat dissipation device 100 provided in the embodiment of the present disclosure is roughly as follows:

A heat dissipation component is installed in each insertion hole 111 of the heat-conducting mounting assembly 10. Then a liquid is introduced into the liquid inlet member 24, the liquid first flows from the connecting assembly 23 connected to the liquid inlet member 24 into the receiving groove 2111 of the bearing member 211, then the liquid flows into the heat dissipation member 212, then the liquid flows through the heat dissipation body 2121 and flows from the connecting assembly 23 connected to the liquid outlet member 25 into the liquid outlet member 25, and finally the liquid flows out from the liquid outlet member 25 and takes away the heat transferred by the component to be cooled.

It is obvious to those skilled in the art that the present disclosure is not limited to the details of the exemplary embodiments described above, and that the present disclosure can be implemented in other specific forms without departing from the spirit or essential features of the present disclosure. Therefore, from any point of view, the embodiments should be regarded as exemplary and non-restrictive, and the scope of the present disclosure is defined by the appended claims rather than the above description, and it is intended that all changes falling within the meaning and scope of the equivalent elements of the claims are included in the present disclosure. Any figure mark in the claims should not be regarded as limiting the claim involved. In addition, it is obvious that the word “comprising” does not exclude other units or steps, and the singular does not exclude the plural.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A heat dissipation device comprising:
a heat-conducting mounting assembly configured to install a component to be cooled and cooperate with the component to be cooled in a heat-conducting manner; and
a heat dissipation mechanism comprising a first heat dissipation assembly and a second heat dissipation assembly, and the first heat dissipation assembly and the second heat dissipation assembly detachably connected and inserted in the heat-conducting mounting assembly;
wherein each of the first heat dissipation assembly and the second heat dissipation assembly comprises a bearing member, a heat dissipation member, a magnetic member, and a magnetic pressing member, the bearing member is arranged on a side of the heat-conducting mounting assembly and a receiving groove penetrates the bearing member, the heat dissipation member is arranged in the receiving groove, a part of the heat dissipation member protrudes out of the receiving groove and extends into the heat-conducting mounting assembly for abutting against the component to be cooled in the heat-conducting mounting assembly, the magnetic member is arranged in the heat dissipation member, the magnetic pressing member covers a notch of the receiving groove of the bearing member and the magnetic pressing member is located on a side of the heat dissipation member facing away from the heat-conducting mounting assembly, the magnetic pressing member is used to act on the magnetic member through a magnetic force, thereby allowing the magnetic member to abut against the heat dissipation member and allowing the heat dissipation member to press against the component to be cooled in the heat-conducting mounting assembly.

2. The heat dissipation device of claim 1, wherein the heat dissipation mechanism further comprises two connecting assemblies, a liquid inlet member, and a liquid outlet member, the two connecting assemblies are respectively arranged on opposite sides of the bearing member of the first heat dissipation assembly and the bearing member of the second heat dissipation assembly, the two connecting assemblies communicate with the receiving groove of each of the bearing member of the first heat dissipation assembly and the bearing member of the second heat dissipation assembly, the liquid inlet member communicates with one of the two connecting assemblies, and the liquid outlet member communicates with the other of the two connecting assemblies, a liquid introduced from the liquid inlet member enters the receiving grooves of the bearing members through the connecting assembly connected to the liquid inlet member flows into the connecting assembly connected to the liquid outlet member after passing through the heat dissipation member, and flows out from the liquid outlet member.

3. The heat dissipation device of claim 2, wherein each of the two connecting assemblies comprises a first connection member and a second connection member, the first connection member is connected to the bearing member of the first heat dissipation assembly, the second connection member is connected to the bearing member of the second heat dissipation assembly, a receiving chamber communicating with the receiving groove of each of the bearing members is formed between the first connection member and the second connection member, the liquid inlet member and the liquid outlet member are both connected to the first connection member and are both in communication with the receiving chamber.

4. The heat dissipation device of claim 3, wherein the first connection member comprises a first connecting body and a recessed portion, the first connecting body is arranged on a side of the bearing member connected to the first connection member, an end of the first connecting body is connected to the bearing member connected to the first connection member, the recessed portion is recessed from another end of the first connecting body, the second connection member comprises a second connecting body and a protruding portion, the second connecting body is arranged on a side of the bearing member connected to the second connection member and corresponds to the first connecting body, an end of the second connecting body is connected to the bearing member connected to the second connection member, the protruding portion is protruding from another end of the second connecting body and inserted into the recessed portion.

5. The heat dissipation device of claim 4, wherein connecting holes are provided at corresponding positions of the protruding portion and the recessed portion, the heat dissipation mechanism further comprises a connecting pin inserted into the connecting holes.

6. The heat dissipation device of claim 1, wherein the bearing member comprises a plurality of receiving grooves arranged side by side along a first direction, and a connecting notch is provided on a groove wall extending along a second direction perpendicular to the first direction between any two adjacent receiving grooves of the plurality of receiving grooves, and the connecting notch communicates with the two adjacent receiving grooves, any two adjacent connecting notches are arranged in a staggered manner.

7. The heat dissipation device of claim 6, wherein the second heat dissipation assembly comprises a plurality of heat dissipation members, each of the plurality of heat dissipation members comprises a heat dissipation body and a plurality of fins connected to the heat dissipation body, the heat dissipation body is arranged in one of the plurality of receiving grooves, a portion of the heat dissipation body protrudes from the receiving groove into the heat-conducting mounting assembly and is configured to abut against the component to be cooled in the heat-conducting mounting assembly, the heat dissipation body comprises a mounting groove, and the plurality of fins are arranged at intervals along the second direction in the mounting groove.

8. The heat dissipation device of claim 7, wherein each of the plurality of heat dissipation members further comprises a mounting body, the mounting body is connected to a side of the heat dissipation body, the mounting body comprises a slot, the magnetic member is arranged in the slot, the magnetic pressing member is used to act on the magnetic member through a repulsive magnetic force.

9. The heat dissipation device of claim 7, wherein the heat dissipation mechanism further comprises a plurality of sealing members, a sealing member of the plurality of sealing members is arranged in a corresponding receiving groove of the plurality of receiving grooves and between the bearing member and the heat dissipation body, each of the plurality of sealing members is configured to seal a gap between the bearing member and the heat dissipation body.

10. The heat dissipation device of claim 9, wherein each of the plurality of sealing members comprises a sealing body and sealing protrusions, the sealing body is arranged between the corresponding receiving groove and the heat dissipation body, the heat dissipation body comprises two adjacent surfaces corresponding to the sealing body, each of the sealing protrusions protrudes from a surface of the sealing body facing the heat dissipation body.

11. An electronic equipment comprising:
a component to be cooled;
a heat dissipation device comprising:
a heat-conducting mounting assembly configured to install the component to be cooled and cooperate with the component to be cooled in a heat-conducting manner; and
a heat dissipation mechanism comprising a first heat dissipation assembly and a second heat dissipation assembly, and the first heat dissipation assembly and the second heat dissipation assembly detachably connected and inserted in the heat-conducting mounting assembly;
wherein each of the first heat dissipation assembly and the second heat dissipation assembly comprises a bearing member, a heat dissipation member, a magnetic member, and a magnetic pressing member, the bearing member is arranged on a side of the heat-conducting mounting assembly and a receiving groove penetrates the bearing member, the heat dissipation member is arranged in the receiving groove, a part of the heat dissipation member protrudes out of the receiving groove and extends into the heat-conducting mounting assembly for abutting against the component to be cooled in the heat-conducting mounting assembly, the magnetic member is arranged in the heat dissipation member, the magnetic pressing member covers a notch of the receiving groove of the bearing member and the magnetic pressing member is located on a side of the heat dissipation member facing away from the heat-conducting mounting assembly, the magnetic pressing member is used to act on the magnetic member through a magnetic force, thereby allowing the magnetic member to abut against the heat dissipation member and allowing the heat dissipation member to press against the component to be cooled in the heat-conducting mounting assembly.

12. The electronic equipment of claim 11, wherein the heat dissipation mechanism further comprises two connecting assemblies, a liquid inlet member, and a liquid outlet member, the two connecting assemblies are respectively arranged on opposite sides of the bearing member of the first heat dissipation assembly and the bearing member of the second heat dissipation assembly, the two connecting assemblies communicate with the receiving groove of each of the bearing member of the first heat dissipation assembly and the bearing member of the second heat dissipation assembly, the liquid inlet member communicates with one of the two connecting assemblies, and the liquid outlet member communicates with the other of the two connecting assemblies, a liquid introduced from the liquid inlet member enters the receiving grooves of the bearing members through the connecting assembly connected to the liquid inlet member flows into the connecting assembly connected to the liquid outlet member after passing through the heat dissipation member, and flows out from the liquid outlet member.

13. The electronic equipment of claim 12, wherein each of the two connecting assemblies comprises a first connection member and a second connection member, the first connection member is connected to the bearing member of the first heat dissipation assembly, the second connection member is connected to the bearing member of the second heat dissipation assembly, a receiving chamber communicating with the receiving groove of each of the bearing members is formed between the first connection member and the second connection member, the liquid inlet member and the liquid outlet member are both connected to the first connection member and are both in communication with the receiving chamber.

14. The electronic equipment of claim 13, wherein the first connection member comprises a first connecting body and a recessed portion, the first connecting body is arranged on a side of the bearing member connected to the first connection member, an end of the first connecting body is connected to the bearing member connected to the first connection member, the recessed portion is recessed from another end of the first connecting body, the second connection member comprises a second connecting body and a protruding portion, the second connecting body is arranged on a side of the bearing member connected to the second connection member and corresponds to the first connecting body, an end of the second connecting body is connected to the bearing member connected to the second connection member, the protruding portion is protruding from another end of the second connecting body and inserted into the recessed portion.

15. The electronic equipment of claim 14, wherein connecting holes are provided at corresponding positions of the protruding portion and the recessed portion, the heat dissipation mechanism further comprises a connecting pin inserted into the connecting holes.

16. The electronic equipment of claim 11, wherein the bearing member comprises a plurality of receiving grooves arranged side by side along a first direction, and a connecting notch is provided on a groove wall extending along a second direction perpendicular to the first direction between any two adjacent receiving grooves of the plurality of receiving grooves, and the connecting notch communicates with the two adjacent receiving grooves, any two adjacent connecting notches are arranged in a staggered manner.

17. The electronic equipment of claim 16, wherein the second heat dissipation assembly comprises a plurality of heat dissipation members, each of the plurality of heat dissipation members comprises a heat dissipation body and a plurality of fins connected to the heat dissipation body, the heat dissipation body is arranged in one of the plurality of receiving grooves, a portion of the heat dissipation body protrudes from the receiving groove into the heat-conducting mounting assembly and is configured to abut against the component to be cooled in the heat-conducting mounting assembly, the heat dissipation body comprises a mounting groove, and the plurality of fins are arranged at intervals along the second direction in the mounting groove.

18. The electronic equipment of claim 17, wherein each of the plurality of heat dissipation members further comprises a mounting body, the mounting body is connected to a side of the heat dissipation body, the mounting body comprises a slot, the magnetic member is arranged in the slot, the magnetic pressing member is used to act on the magnetic member through a repulsive magnetic force.

19. The electronic equipment of claim 17, wherein the heat dissipation mechanism further comprises a plurality of sealing members, a sealing member of the plurality of sealing members is arranged in a corresponding receiving groove of the plurality of receiving groove and between the bearing member and the heat dissipation body, each of the plurality of sealing members is configured to seal a gap between the bearing member and the heat dissipation body.

20. The electronic equipment of claim 19, wherein each of the plurality of sealing members comprises a sealing body and sealing protrusions, the sealing body is arranged between the corresponding receiving groove and the heat dissipation body, the heat dissipation body comprises two adjacent surfaces corresponding to the sealing body, each of the sealing protrusions protrudes from a surface of the sealing body facing the heat dissipation body.
